(19) United States
(12) Patent Application Publication
(10) Pub. No.: US 2006/0202209 A1
(43) Pub. Date: Sep. 14, 2006

(54) Limiting net curvature in a wafer

(76) Inventors: Maxim B. Kelman, Mountain View, CA (US); Shriram Ramanathan, Portland, OR (US); Kramadhati V. Ravi, Atherton, CA (US)

Correspondence Address: INTEL/BLAKELY, 12400 WILSHIRE BOULEVARD, SEVENTH FLOOR, LOS ANGELES, CA, 90025-1030, US

(21) Appl. No.: 11/077,532

(22) Filed: Mar. 9, 2005

(51) Int. Cl. H01L 31/0312

(52) U.S. Cl. 257/77

(57) ABSTRACT

A method and apparatus for limiting net curvature in a substrate is provided. A layer is formed on one side of a substrate to limit curvature that may be introduced in the substrate by formation of a thermal spreading layer on an opposing side of the substrate. For example, introduction of a diamond layer on a substrate to dissipate thermal energy away from a semiconductor layer may introduce tensile or compressive stress in the substrate and result in undesirable bowing and/or warping of the substrate. To limit this curvature, a curvature limiting layer, e.g. another diamond layer, may be formed on subjacent to the substrate.

### FIELD

The field of the invention relates to the field of semiconductor processing and in particular, to a method and apparatus for limiting net curvature in a wafer.

### BACKGROUND

Integrated circuits (ICs) can include thousands or millions of semiconductor devices, mostly transistors. These devices generate heat which may be dissipated to maintain the devices at an acceptable operating temperature.

Because of the relatively high thermal conductivity of diamond, effort has been made to integrate a diamond carbon layer into ICs to dissipate thermal energy. However, such efforts often result in curvature of the wafer (e.g. local bowing and/or global warping) at room temperature, making subsequent processing prohibitively difficult. This curvature is often due to differences in the coefficient of thermal expansion (CTE) (defined as the fractional change in length per unit change in temperature) between carbon and the wafer material. The difference in the CTE between the carbon layer and the wafer material may result in biaxial stress, such as tensile or compressive stress, in the carbon layer which may cause the wafer to curve.

Therefore, what is needed is a method and apparatus for limiting curvature of a wafer.

### BRIEF DESCRIPTION OF THE DRAWINGS

Various embodiments of the present invention are set forth in the following drawings in which:

FIG. 1 is a cross-sectional side view of an integrated circuit having carbon layers above and below a substrate in accordance with one embodiment of this invention.

FIGS. 2A-2G are cross-sectional side views of a wafer at various stages of a process to form a semiconductor device in accordance with one embodiment of this invention. Specifically:

FIG. 2A is a cross-sectional side view of a wafer substrate.

FIG. 2B is a cross-sectional side view of a wafer with a first carbon layer formed over a substrate and a second carbon layer formed below the substrate.

FIG. 2C is a cross-sectional side view of the wafer of FIG. 2B with a buffer layer formed over the first carbon layer.

FIG. 2D is a cross-sectional side view of the wafer of FIG. 2C and a semiconductor donor wafer.

FIG. 2E is a cross-sectional side view of the wafer of FIG. 2D with the semiconductor donor wafer bonded to a handle wafer.

FIG. 2F is a cross-sectional side view of the wafer of FIG. 2E with the semiconductor layer cleaved.

FIG. 2G is a cross-sectional side view of the wafer of FIG. 2F with a device formed in the semiconductor layer.

FIG. 3 is a cross-sectional side view of another semiconductor device having a thermal energy spreading layer and curvature limiting layer in accordance with another embodiment of this invention.

FIG. 4 is a cross-sectional side view of another semiconductor device having a plurality of heat-spreading carbon layers in accordance with another embodiment of this invention.

FIG. 5 is a cross-sectional side view of another semiconductor device having a heat-spreading carbon layer and a buried oxide layer in accordance with another embodiment of this invention.

FIG. 6 is a cross-sectional side view of a semiconductor device after removal of the second carbon layer in accordance with another embodiment of this invention.

FIG. 7 illustrates a system in accordance with one embodiment of this invention.

### DETAILED DESCRIPTION

Generally, a method and apparatus for limiting wafer curvature is disclosed. In the following detailed description, numerous specific details are set forth in order to provide a thorough understanding of embodiments of the present invention. However, it will be apparent to one of ordinary skill in the art that these specific details need not be used to practice embodiments of the present invention. In other circumstances, well-known structures, materials, or processes have not been shown or described in detail so as not to obscure embodiments of the present invention.

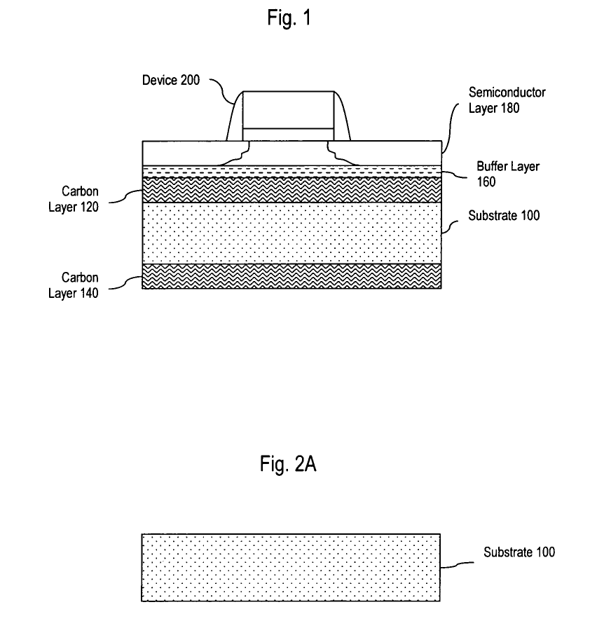

FIG. 1 is a cross-sectional side view of an integrated circuit having carbon layers above and below a substrate in accordance with one embodiment of this invention. Generally, in FIG. 1, carbon layers 120 and 140 are formed on opposing surfaces of substrate 100 (e.g. a monocrystalline silicon substrate). Buffer layer 160 (e.g. a polysilicon layer) is formed over carbon layer 120, facilitating the formation of semiconductor layer 180 on the wafer. Device 200 is formed in semiconductor layer 180. Carbon layer 120 dissipates heat generated by the device in semiconductor layer 180 away from the device and semiconductor layer 180. Formation and properties of these layers will be described in more detail below.

Generally, the formation of carbon layer 120 over substrate 100 may introduce undesirable stress in the substrate. Such stress may cause the substrate to curve.

To limit undesirable stress in substrate 100, carbon layer 140 introduces an opposing stress. For example, if carbon layer 120 introduces compressive stress on one side of substrate 100 such that substrate 100 curves downward, carbon layer 140 also introduces compressive stress, but on an opposing side of substrate 100 so as to limit (e.g. confine, reduce or eliminate) the downward curvature. Therefore, carbon layer 120 and 140, together, introduce zero or minimal curvature in substrate 100.

Similarly, if carbon layer 120 introduces tensile stress on one side of substrate 100 such that substrate 100 curves upward, carbon layer 140 also introduces tensile stress, but on an opposing side of substrate 100 so as to limit (e.g. confine, reduce or eliminate) the upward curvature. Therefore, again, carbon layer 120 and 140 together introduce zero or minimal curvature in substrate 100.

Therefore, generally in the embodiment of FIG. 1, a first carbon layer dissipates thermal energy away from the device layer, while a second carbon layer limits undesirable wafer curvature that may result from introduction of the first carbon layer. Such limiting of wafer curvature may facilitate subsequent processing. For example, such limiting may produce a relatively planar wafer on which dies may be more readily attached and heat may be more uniformly spread (e.g. during assembly and testing).

Various embodiments of the present invention and methods for forming those embodiments will now be described in more detail.

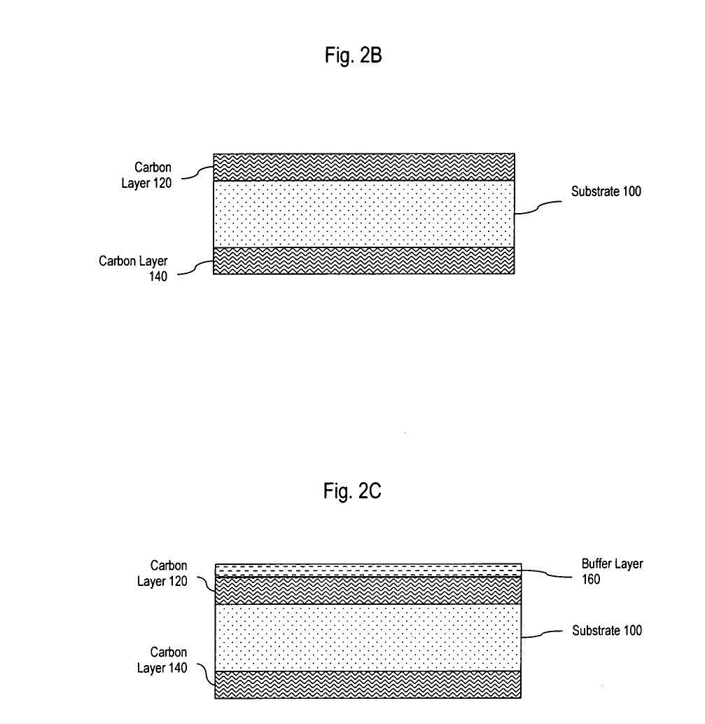

FIGS. 2A-2G are cross-sectional side views of a wafer at various stages of a process to form a semiconductor device in accordance with one embodiment of this invention. Specifically, FIG. 2A is a cross-sectional side view of a wafer substrate. Substrate 100 is a semiconductor material, e.g. silicon. In one embodiment, substrate 100 is a monocrystalline silicon substrate.

Carbon layers are formed on opposing sides of substrate 100, as shown in FIG. 2B. Specifically, FIG. 2B is a cross-sectional side view of a wafer with a first carbon layer 120 formed over a substrate 100 and a second carbon layer formed under substrate 100. Layer 120 and 140 may be formed simultaneously or sequentially.

Simultaneous formation of the first and second carbon layer may reduce processing time. For example, in one embodiment, carbon layers 120 and 140 are formed in a hot filament CVD reactor. The wafer is centered inside the reactor such that both carbon layers are formed simultaneously and to similar thickness. Because both layers are formed simultaneously to similar thickness, they cause equal or near equal stress, but on opposing sides of substrate 100.

For example, in one embodiment, a diamond layer is formed over a silicon substrate. Because the coefficient of thermal expansion of diamond differs from that of silicon, the diamond layer and silicon substrate will contract by different amounts as the wafer cools after deposition, thereby resulting in biaxial stress in the film. This biaxial stress may cause the wafer to curve.

The tensile or compressive nature of the biaxial stress and its magnitude depend on the diamond deposition temperature. At or above 700° C., the CTE of diamond is higher than that of silicon. For example, at about 925° C., the CTE of diamond is approximately 5 ppm/C while the CTE of silicon is approximately 4.3 ppm/C. Under these conditions, the diamond contracts more than the silicon as the wafer cools, thereby introducing tensile stress in the silicon. Thus, in the example above, because the diamond layer is formed over the silicon substrate, the tensile stress causes an upward bending moment. This moment may result in an upward wafer curvature.

In contrast, at below about 700° C., the CTE of diamond is lower than that of silicon. For example, at about 525°° C., the CTE of diamond is approximately 3.8 ppm/C while the CTE of silicon is approximately 4 ppm/C. Under these conditions, the diamond contracts less than the silicon as the wafer cools, thereby introducing compressive stress in the silicon. Thus, in the example above, because the diamond layer is formed over the silicon substrate, the compressive stress causes a downward bending moment. This moment may result in a downward wafer curvature.

In both examples above, if carbon layers 120 and 140 are diamond formed simultaneously, whether above or below 700° C., layers 120 and 140 will induce equal and opposite bending moments on the substrate, thereby limiting net wafer curvature.

In other embodiments, layers 120 and 140 may be formed sequentially, rather than simultaneously. Sequential formation allows layers 120 and 140 to have different deposition conditions and different properties. Sequential formation includes formation of carbon layer 120 before layer 140, as well as formation of carbon layer 120 after layer 140.

As an example of an embodiment in which carbon layer 120 is formed before layer 140, in one embodiment, carbon layer 120 is first formed in a plasma enhanced chemical vapor deposition (PECVD) reactor to a certain thickness. This thickness, along with other properties such as diamond-to-graphite ratio, is sufficient to provide a certain thermal conductivity. For example, in one embodiment, carbon layer 120 is composed entirely or almost entirely of diamond, and formed to a thickness of between 30 to 50 microns, providing a thermal conductivity of about 2000 W/m-K.

Subsequent to the formation of layer 120, the location of the wafer in the reactor may be adjusted allow formation of carbon layer 140 to limit the curvature which may have been introduced into the substrate by the prior formation of carbon layer 120 on the substrate.

In embodiments in which the diamond-to-graphite ratio, granularity and deposition conditions of carbon layer 120 and 140 are similar, carbon layer 140 may be formed to a thickness approximately equal to that of carbon layer 120 to achieve zero or near zero bowing and/or warping of the wafer. For example, in certain embodiments, both layers 120 and 140 are composed entirely or almost entirely of diamond, with a granularity of approximately 1-5 microns, formed at temperatures of approximately 600-1000° C. In this embodiment, layers 120 and 140 may be formed to approximately equal thickness to achieve zero or near zero curvature of the wafer. In particular, in certain embodiments, that thickness is between approximately 10 to 100 microns. In one particular embodiment, both layer 120 and layer 140 are composed entirely or almost entirely of diamond, with a granularity of approximately 1-5 microns, formed at temperatures of approximately 800-900° C., to a thickness of approximately 30-50 microns.

Generally, whether deposited sequentially or simultaneously, formation of layer 140 with similar deposition conditions and properties (e.g. diamond-to-graphite ratio and thickness) as layer 120 will induce an opposing bending moment on substrate 100 of a magnitude approximately equal to that induced by layer 120, thereby resulting in zero or near zero net bending moment and curvature in substrate 100.

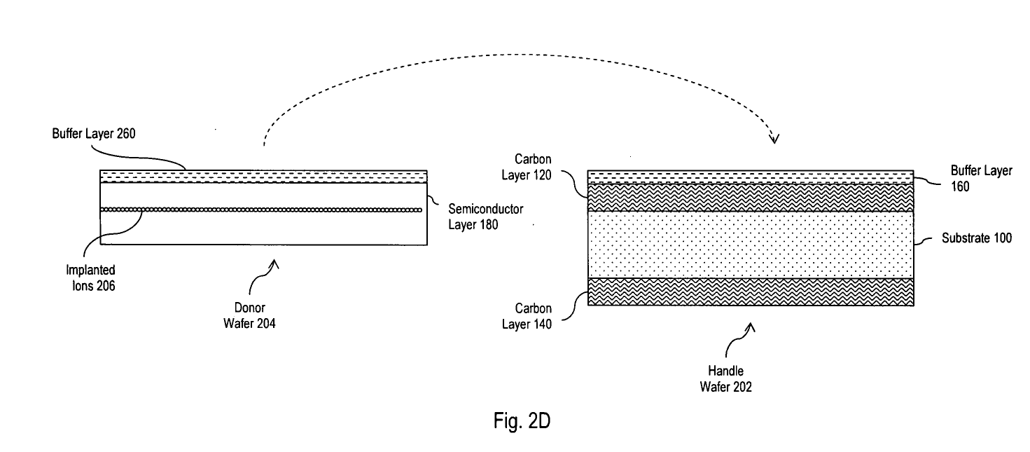

Alternatively, in other embodiments, the deposition conditions and/or properties of layer 140 may differ from that of layer 120. For example, layer 140 may be formed at a different temperature than layer 120. Layer 140 may also contain graphite while carbon layer 120 may contain no graphite. When the deposition conditions and/or properties of layer 140 differ from that of layer 120, several methods may be used to achieve zero or near zero curvature of the substrate. For example, layer 140 may be formed to a different thickness than that of layer 120, e.g. in embodiments similar to that shown in FIG. 3 in which the curvature limiting layer is thinner than the thermal spreading layer.

Alternatively or in addition to altering layer thickness, another variable may be altered, such as the deposition condition, diamond-to-graphite ratio or granularity of layer 140. That is, the layer thickness, deposition temperature, diamond content and granularity all or each may be varied during formation of either or both layer 120 and 140 to achieve a certain stress level in the substrate.

In certain embodiments, carbon layer 120 may be formed with a sufficiently large granularity such that the certain stress state in substrate 100 is achieved by inducing minimal or no counteracting stress by layer 140. For example, in one embodiment, layer 120 is diamond with a granularity of over 6 microns deposited under conditions which results in an acceptable range of curvature in the substrate. In that embodiment, layer 140 may induce minimal or no counteracting stress.

Layers 120 and layer 140 may be formed using a variety of methods. For example, either layer 120 or 140 may be formed by depositing carbon particles directly onto substrate 100. In one embodiment, as previously mentioned, plasma enhanced chemical vapor deposition (PECVD) processes are used to deposit the carbon particles. Use of PECVD processes allow for the creation of a high atomic hydrogen current along with the carbon source, which promotes the formation of diamond rather than graphite. Carbon layers with higher diamond content have higher thermal conductivity. In one embodiment, a carbon layer with a thermal conductivity of between 1000 W/m-K and 2000 W/m-K is formed using a PECVD reactor at approximately 2 to 5 KW. Other embodiments may use other reactors, e.g. hot-filament CVD, microwave-enhanced CVD, DC charged CVD and arc-jet CVD.

Alternatively, either carbon layer 120 or 140 may be grown on a nucleation layer. This nucleation layer may be formed by abrading the surface of substrate 100 to form a layer of damaged substrate. In one embodiment, the substrate is abraded by polishing the substrate with an abrasive grit, such as diamond powder of 0.1 to 10 microns, either mechanically or by ultrasonic agitation. In another embodiment, the substrate is abraded by ion bombardment. For example, the substrate may be placed in a microwave deposition reactor and a negative biased of a few hundred volts added to the substrate. Ions are then allowed to abrade the surface.

Alternatively, a nucleation layer may be formed by depositing a solution on the surface of substrate 100 to form a film. For example, in one embodiment, the solution is an acetone solvent with a suspension of nano-crystalline diamond particles. The solution may be deposited on substrate 100 using known methods, such as by spraying or spinning. When the solvent evaporates, a thin film of diamond particles remains on substrate 100, on which a carbon layer may be grown. In other embodiments, the solution may include diamond-like amorphous carbon, metal carbide or graphite.

The properties and formation conditions of layer 140 depend on the properties and formation conditions of layer 120, whether layer 120 and layer 140 are formed simultaneously or sequentially. The properties and formation conditions of layer 120, in turn, depend on the thermal dissipation desired.

For example, to effectively spread thermal energy in one embodiment, layer 120 is formed to be between 10 to 100 microns thick. In one particular embodiment on a 300 mm wafer, carbon layer 120 is formed to be between 10 and 15 microns thick. Layer 140 then may then be formed to a similar thickness, simultaneously or sequentially.

In other embodiments, to effectively spread thermal energy, carbon layer 120 may be formed to have a high diamond-to-graphite content. As previously mentioned, carbon layers with higher diamond content have higher thermal conductivity; and therefore dissipate heat more effectively. The presence of graphite in a carbon layer generally reduces the thermal conductivity of the layer. Therefore, all other factors being equal, embodiments in which a carbon layer is mostly or all diamond dissipates more thermal energy than embodiments in which the carbon layer contains graphite. Thus, in certain embodiments, carbon layer 120 may be entirely diamond. However, it will be appreciated that in other embodiments, carbon layer may contain both graphite and diamond. For example, in one embodiment, a layer containing both graphite and diamond may have a thermal conductivity below 2000 W/m-K. In other embodiments, the thermal conductivity may be 200 to 300 W/m-K, with thermal conductivity decreasing as the amount of graphitic material in the film increases. Layer 140 then may then be formed, simultaneously or sequentially, under particular deposition conditions with particular properties to limit curvature in the substrate.

Though diamond is particularly beneficial because of diamond's relatively high thermal conductivity, a thermal spreading layer (e.g. layer 120) generally may be composed of material other than carbon, as will be discussed in further detail below. Similarly, a curvature limiting layer (e.g. layer 140) generally may also be composed of material other than carbon, as also will be discussed in further detail below.

Following formation of layers 120 and 140, either simultaneously or sequentially, a buffer layer is formed on layer 120, as shown in FIG. 2C. FIG. 2C is a cross-sectional side view of the wafer of FIG. 2B with a buffer layer formed over the layer 120. In one embodiment, buffer layer 160 is a polycrystalline, e.g. polycrystalline silicon. Buffer layer 160 is sufficiently thick to cover the rough surfaces of carbon layer 120. However, buffer layer is sufficiently thin to allow heat transfer. In one embodiment, buffer layer 160 is between approximately 5 to 20 microns thick. Buffer layer 160 facilitates bonding of semiconductor layer 180 to the wafer. Buffer layer 160 may be smoothed or polished as necessary before formation of semiconductor layer 180.

In certain embodiments, the semiconductor layer may be formed by bonding a semiconductor to the buffer layer using a layer transfer process. FIGS. 2D-2F show various stages of a layer transfer bonding process according to one embodiment of the invention. In FIG. 2D, to form a semiconductor layer of a certain thickness on the wafer, a donor wafer 204 composed of a semiconductor material, e.g. monocrystalline silicon, is first implanted with hydrogen ions (or ions of other light elements) 206 to form a weakened semiconductor layer. This ion implantation method is used in layer transfer processes such as SmartCut® (also known as Unibond® or IonCut®) and NanoCleave™. In other embodiments, rather than implanting ions, a layer of porous silicon is used to form the splitting layer. The layer of porous silicon may be formed by anodic etching and annealing as in, for example, the ELTRAN™ process.

Buffer layer 260, e.g. a polycrystalline, on donor wafer 204 may then be bonded to buffer layer 160 on handle wafer 202, as suggested by FIG. 2D. The result of the bonding is shown in FIG. 2E. The weakened semiconductor layer is then cleaved away along the layer of implanted ions 206, leaving a semiconductor layer 180 with a certain thickness, as shown in FIG. 2F. Following cleaving, the remaining semiconductor layer may be polished as necessary before device 200 is formed in the semiconductor, as shown in FIG. 2G.

Alternatively, in other embodiments, buffer layer 160 may facilitate bonding of semiconductor layer 180 to the wafer by facilitating growth of semiconductor layer 180. For example, in certain embodiments, buffer layer 160 may be composed of a raw material (e.g. quartzite) refined into electronic grade polysilicon. The polysilicon buffer layer may be used to grow a single crystal silicon to a certain thickness to form semiconductor layer 180. The single crystal may be grown by either Czochralski (CZ) crystal growth or float zone (FZ) growth, for example.

Alternatively, in yet other embodiments, buffer layer 160 may facilitate formation of semiconductor layer 180 on the wafer by bonding to a previously formed single crystal silicon. The single crystal silicon may then be ground to a certain thickness. Semiconductor layer 180 may be any semiconductor material, including silicon, germanium, gallium arsenide, aluminum arsenide, aluminum gallium arsenide, boron nitride, gallium nitride, indium phosphide, silicon carbide and silicon germanium.

After semiconductor layer 180 is bonded to the wafer, the layer may be doped to facilitate formation of device 200. For example, semiconductor layer 180 may be doped with boron or aluminum to produce extra holes, or phosphorous or arsenic to produce extra electrons, as desired for the formation of devices such as P-Channel Metal-Oxide Semiconductor Field Effect Transistors (PMOS transistors) or N-channel Metal-Oxide Semiconductor Field Effect Transistors (NMOS transistors). Device 200 may be any semiconductor device formed on a wafer, such as a transistor. For example, in certain embodiments, device 180 may be a two terminal devices (e.g. semiconductor diode, Zener diode, light emitting diode, PIN diode, Schottky diode, avalance diode, laser diode or DIAC diode), a three terminal device (e.g. PMOS transistor, NMOS transistor, bipolar transistor, Darlington transistor, Thyristor and Triac), or a four terminal device (e.g. Hall effect sensor).

Thus, as shown in FIG. 2G, a carbon layer 120 is formed over a substrate 100 to dissipate thermal energy away from a semiconductor layer 180 and a device 200. Carbon layer 140 is formed below the substrate 100 to limit curvature introduced into the substrate 100 by layer 120 by providing an opposing, counteracting stress and bending moment in the substrate.

As previous mentioned, a thermal spreading layer (e.g. layer 120) may generally be composed of material other than carbon, and a curvature limiting layer (e.g. layer 140) may also generally be composed of material other than carbon. FIG. 3 is a cross-sectional side view of another semiconductor device having a thermal energy spreading layer and curvature limiting layer in accordance with another embodiment of this invention. FIG. 3 shows one embodiment of the present invention in which a thermal spreading layer 320 may or may not be carbon, and a curvature limiting layer 340 may or may not be carbon and/or may or may not have properties similar to that of layer 340.

Specifically, in FIG. 3, curvature limiting layer 340 does not have a thickness equal to that of thermal spreading layer 320. Additionally, in FIG. 3, curvature limiting layer 340 has different properties from thermal spreading layer 320. For example, curvature limiting layer 340 may be formed at a different temperature, have different granularity and/or have a different diamond-to-graphite ratio than layer 320. Curvature limiting layer 340 also may be formed from other material, e.g. silicon nitride or silicon carbon.

However, regardless of the differences between curvature limiting layer 340 and thermal spreading layer 320, curvature limiting layer 340 acts to limit a bending moment that may otherwise exist in substrate 100 due to thermal spreading layer 320. By introducing an equal and opposing bending moment in substrate 100, curvature of substrate 100 is limited. In certain embodiments, the curvature limiting layer may be removed following formation of devices, e.g. device 200, as will be discussed in further detail below.

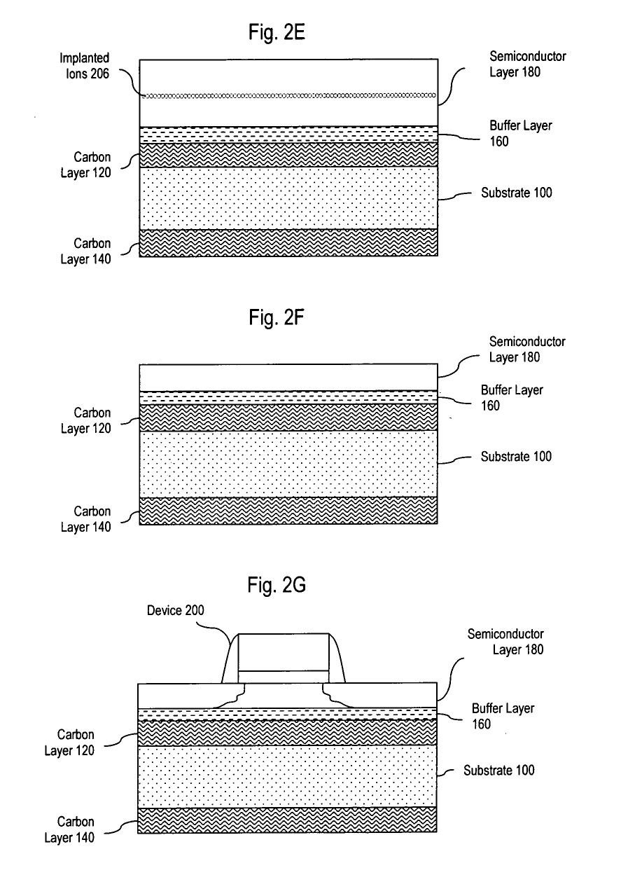

In embodiments in which layer 340 is composed of material with a high thermal conductivity (e.g. diamond), layer 340 may also dissipate thermal energy away from a second semiconductor layer, as shown in the embodiment of FIG. 4.

FIG. 4 is cross-sectional side view of another semiconductor device having a plurality of heat-spreading carbon layers in accordance with another embodiment of this invention. In FIG. 4, both layers 120 and 140 dissipate thermal energy. In particular, layer 120 dissipates thermal energy away from semiconductor layer 180 and layer 140 dissipates thermal energy away from semiconductor layer 480. In addition, both layers 120 and 140 act to limit curvature of substrate 100 that may be introduced by the other layer. In particular, layer 120 acts to limit bowing and/or warping of substrate 100 that may be introduced by layer 140, and layer 140 acts to limit bowing and/or warping of substrate 100 that may be introduced by layer 12. Thus, in the embodiment shown in FIG. 4, devices may be formed on both side of substrate 100 and benefit from the thermal properties of layers 120 and 140, as well as benefit from being formed on a substrate with a certain curvature, e.g. zero or near zero wafer bow.

These devices may be formed sequentially or simultaneously. For example, in certain embodiments, device 200 may be formed on layer 180 before device 400 is formed on layer 480. In other embodiments, device 200 may be formed simultaneously with device 400. For example, gate dielectrics for devices 200 and 400 may be formed before gate electrodes for devices 200 and 400 are formed.

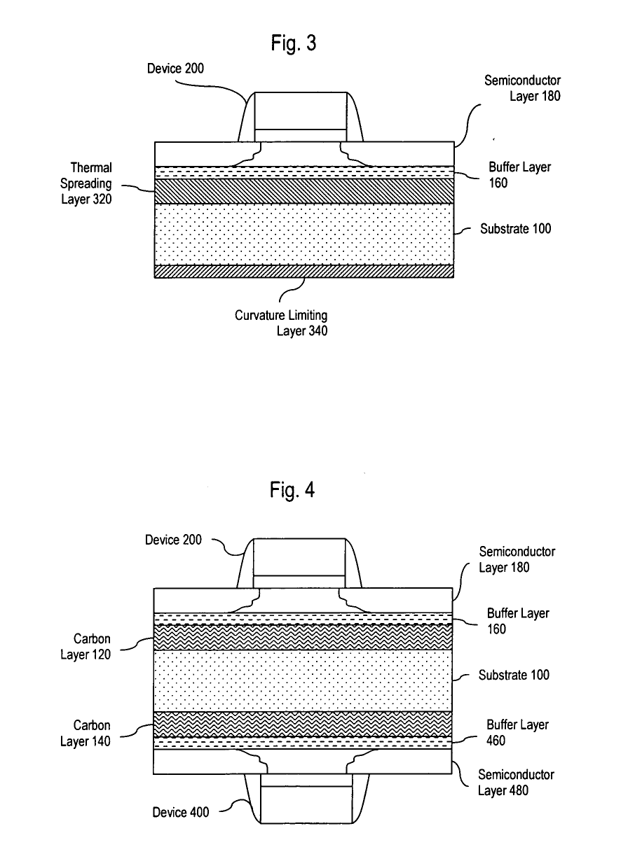

FIG. 5 is a cross-sectional side view of another semiconductor device having a heat-spreading carbon layer in accordance with another embodiment of this invention. The embodiment of FIG. 5 incorporates a buried oxide layer, similar to those in known silicon-on-insulator (SOI) devices. Specifically, in FIG. 5, a buried oxide layer is formed between buffer layer 160 and semiconductor layer 180. In one embodiment, buried oxide layer 520 is silicon dioxide. The buried oxide layer reduces leakage current. Therefore, the embodiment shown in FIG. 5 may benefit from not only reduced leakage current via a buried oxide layer, but may also benefit from cooling via a thermal energy spreading layer and from fabrication on a relatively planar wafer (e.g. during assembly and testing).

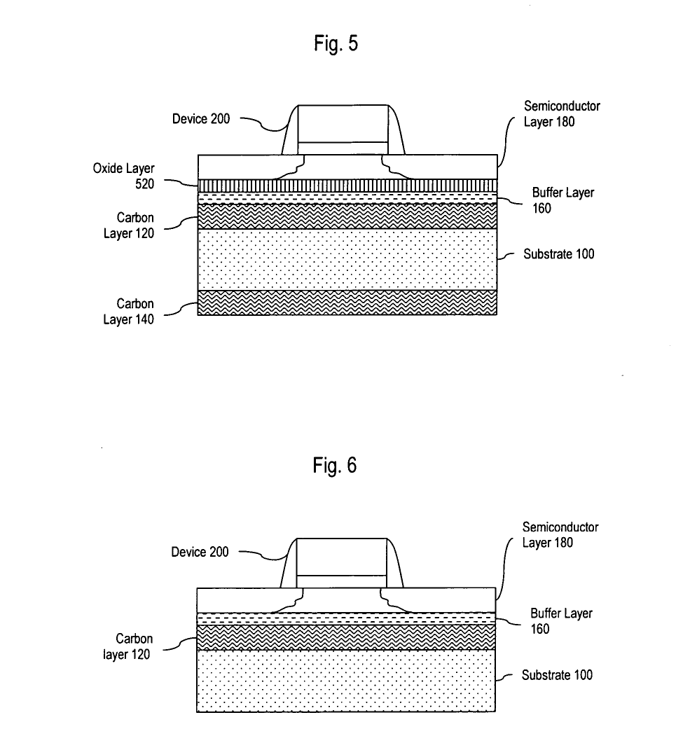

Once the fabrication process is complete, wafer bow limiting layer (e.g. layer 140 or layer 340) may be removed if desired. FIG. 6 is cross-sectional side view of a semiconductor device after removal of the curvature limiting layer in accordance with one embodiment of this invention. The curvature limiting layer may be removed using various methods. For example, in one embodiment of the invention, carbon layer 140 is oxidized using oxygen in reactive ion-etching to transform carbon layer 140 into carbon dioxide. In another embodiment, curvature limiting carbon layer 140 is thinned through grinding.

Removal of a curvature limiting layer may be desirable, for example, in certain embodiments in which stress in particular regions of a wafer may increase channel mobility, as discussed in co-pending, co-assigned U.S. patent application Ser. No. ______, entitled “Stressed Semiconductor Using Carbon and Method for Producing the Same” and filed _. In those embodiments, curvature limiting layer (e.g. layer 140 or layer 340) may be removed following fabrication to re-induce stress from the bending moment in the semiconductor.

In other embodiments, removal of a curvature limiting layer may not be desirable. For example, in the embodiment of FIG. 4, layers 120 and 140 both act as both a curvature limiting layer and a thermal spreading layer. In such an embodiment, removal of either layer 120 or layer 140 may be counterproductive. In other embodiments, removal of a curvature limiting layer may incur sufficient costs to make removal undesirable. Therefore, it shall be appreciated that a curvature limiting layer (e.g. layer 140 or 340) may or may not be removed following formation of a device (e.g. 200), and still remain within the scope of embodiments of this invention.

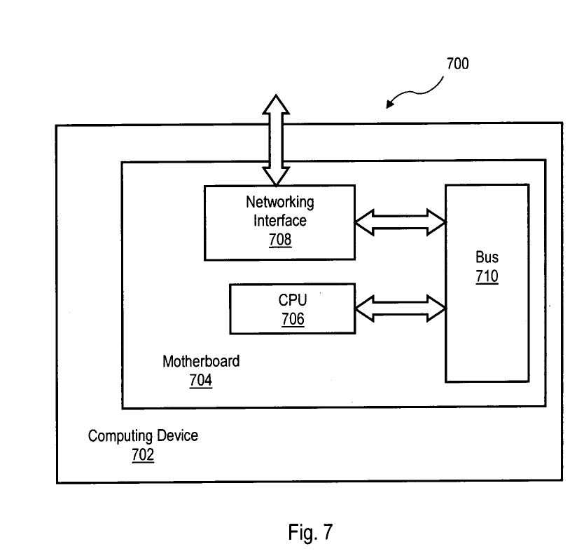

FIG. 7 illustrates a system in accordance with one embodiment of this invention. As illustrated, for the embodiment, system 700 includes computing device 702 for processing data. Computing device 702 may include a motherboard 704. Motherboard 704 may include in particular a processor 706, and a networking interface 708 coupled to a bus 710. More specifically, processor 706 may comprise devices 200 or 400.

Depending on the applications, system 700 may include other components, including but are not limited to volatile and non-volatile memory, a graphics processor, a digital signal processor, a crypto processor, a chipset, mass storage (such as hard disk, compact disk (CD), digital versatile disk (DVD) and so forth), and so forth. One or more of these components may also include the earlier described curvature limiting carbon layer.

In various embodiments, system 700 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

Thus, a method and apparatus for limiting net curvature in a wafer is disclosed. Although the figures and descriptions have details with regards to bulk wafers, it shall be appreciated that the same methodology may be applied to other semiconductor designs, such as dual gate and trigate transistor designs. In addition, although the figures and descriptions have detailed formation of a single device in the semiconductor layer, it will be appreciated that the same methodology may be applied to form multiple devices in the semiconductor layer.

Additionally, although the present invention is described herein with reference to specific embodiments, many modifications and variations therein will readily occur to those with ordinary skill in the art. Accordingly, all such variations and modifications are included within the intended scope of embodiments of the present invention as defined by the following claims.

1. An apparatus, comprising:
a thermal spreading first carbon layer disposed on one side of a substrate; and
a second carbon layer disposed on an opposing side of the substrate.

2. The apparatus of claim 1, wherein the second carbon layer is disposed to stress the substrate to produce zero net curvature in the substrate.

3. The apparatus of claim 1, wherein the first carbon layer is disposed to subject said one side of the substrate to compressive stress and the second carbon layer is disposed to subject said opposing side of the substrate to compressive stress equally to limit net curvature in the substrate.

4. The apparatus of claim 1, wherein the first carbon layer is disposed to subject said one side of the substrate to tensile stress and the second carbon layer is disposed to subject said an opposing side of the substrate to tensile stress equally to limit net curvature in the substrate.

5. The apparatus of claim 1, wherein the first and second carbon layers are diamond.

6. The apparatus of claim 1, wherein the first carbon layer has a thermal conductivity of about 1000 to 2000 W/mK.

7. The apparatus of claim 1, further comprising a semiconductor layer directly disposed on the first carbon layer.

8. An apparatus, comprising:
a device formed in a semiconductor layer;
a buffer layer formed subjacent to the semiconductor layer;
a first diamond layer formed subjacent to the buffer layer;
a substrate formed subjacent to the first diamond layer; and
a second diamond layer formed subjacent to the substrate.

9. The apparatus of claim 8, wherein the first and second diamond layers are each approximately 10 to 100 microns thick.

10. The apparatus of claim 8, wherein the first and second diamond layers each comprise of diamond grains approximately 1 to 5 microns in diameter.

11. The apparatus of claim 8, wherein the device is a transistor.

12. The apparatus of claim 8, wherein the buffer layer is polysilicon polycrystalline.

13. A method, comprising:
forming a first carbon layer on one side of a substrate; and
forming a second layer on an opposing side of the substrate to limit net curvature in the substrate.

14. The method of claim 13, wherein the second layer is carbon.

15. The method of claim 13, wherein the second layer is silicon nitride or silicon carbon.

16. The method of claim 14, wherein the first and second carbon layers are to be formed simultaneously.

17. The method of claim 14, wherein the second carbon layer is to be formed subsequent to forming the first carbon layer.

18. The method of claim 17, wherein the first and second carbon layers are to be formed at different temperatures, and the first and second carbon layers are to be of unequal thickness.

19. The method of claim 14, wherein the first and second carbon layers are to be formed at approximately 600 to 1000 degrees Celsius.

20. The method of claim 14, wherein the first carbon layer is to have a thermal conductivity of about 1000 to 2000 W/mK.

21. The method of claim 14, further comprising:
forming first buffer layer superjacent to the first carbon layer;
forming a first semiconductor layer superjacent to the first buffer layer; and
forming a first device in the first semiconductor layer.

22. The method of claim 21, further comprising:
forming a second buffer layer subjacent to the second carbon layer;
forming a second semiconductor layer subjacent to the second buffer layer; and
forming a second device in the second semiconductor layer.

23. The method of claim 21, further comprising:
forming an oxide layer between the first buffer layer and the first semiconductor layer.

24. A method, comprising:
forming a first diamond layer on one side of a substrate;
simultaneously forming a second diamond layer on opposing sides of a substrate;
forming a buffer layer superjacent to the first diamond layer;
forming a semiconductor layer superjacent to the buffer layer; and
forming a device in the semiconductor layer, wherein the first diamond layer is to spread thermal energy away from the semiconductor layer and the second diamond layer is to limit net curvature in the substrate.

25. The method of claim 24, wherein the first and second diamond layers have equal thickness of approximately 10 to 100 microns and the substrate is approximately 300 mm thick.

26. The method of claim 24, wherein forming the first and second carbon layers comprises depositing the first and second carbon layers in a plasma enhanced chemical vapor deposition (CVD) reactor.

27. The method of claim 24, wherein forming the semiconductor layer comprises
forming a planarized polycrystalline layer superjacent to the first diamond layer; and
growing an epitaxy silicon layer on the polycrystalline layer.

28. A method, comprising:
forming a first carbon layer on one side of a substrate;
forming a second carbon layer on an opposing side of the substrate to limit curvature in the substrate;
forming a semiconductor layer superjacent to the first carbon layer;
forming a device in the semiconductor layer;
removing the second carbon layer; and
planarizing the substrate.

29. The method of claim 28, wherein removing the second carbon layer comprises oxidizing the second carbon layer.

30. The method of claim 28, wherein planarizing the substrate comprises back-grinding the substrate.

31. A method, comprising:
depositing a first diamond layer on one side of a semiconductor substrate;
depositing a second diamond layer on an opposing side of the semiconductor substrate;
forming a polysilicon buffer layer superjacent to the first diamond layer;
bonding a silicon layer to the buffer layer;
cleaving the silicon layer; and
forming a device in the silicon layer.

32. The method of claim 31, wherein device is a transistor.

33. The method of claim 31, wherein bonding the silicon layer comprises:
polishing the buffer layer; and
growing the silicon layer on the polished buffer layer in an epitaxial reactor.
